(19) United States
(12) Patent Application Publication
(10) Pub. No.: US 2014/0332671 A1
(43) Pub. Date: Nov. 13, 2014

(54) PHOTON COUNTING CONTROLLER, RADIOGRAPHIC IMAGING APPARATUS, AND CONTROL METHOD OF PHOTON COUNTING CONTROLLER

(71) Applicant: SAMSUNG ELECTRONICS CO., LTD., Suwon-si (KR)

(72) Inventors: Kang Ho LEE, Hwaseong-si (KR); Young KIM, Yongin-si (KR); Jin Myoung KIM, Hwaseong-si (KR); Young Hun SUNG, Hwaseong-si (KR)

(73) Assignee: SAMSUNG ELECTRONICS CO., LTD., Suwon-si (KR)

(21) Appl. No.: 14/271,787

(22) Filed: May 7, 2014

(30) Foreign Application Priority Data
May 7, 2013 (KR) 10-2013-0051358

(51) Int. Cl. H03F 3/08

(52) U.S. Cl. CPC H03F 3/08
USPC 250/214 A

(57) ABSTRACT

The photon counting controller includes an amplification controller to charge an input electrical signal, to amplify the input electrical signal, and to discharge the charged electrical signal, a charge controller to control a charge and a discharge of the electrical signal of the amplification controller based on a received feedback signal, and a measuring controller to compare voltage of the amplified electrical signal with reference voltage and to count photons based on a result of comparison.

### CROSS-REFERENCE TO RELATED APPLICATION

This application claims priority from Korean Patent Application No. 10-2013-0051358, filed on May 7, 2013 in the Korean Intellectual Property Office, the disclosure of which is incorporated herein by reference in its entirety.

### BACKGROUND

1. Field

Apparatuses and methods consistent with exemplary embodiments relate to a photon counting controller, a control method of the photon counting controller, and a radiographic imaging apparatus.

2. Description of the Related Art

A radiographic imaging apparatus is an imaging system that emits radiation, such as X-rays, to an object, such as a human body or an article, to acquire an internal image of the object. Specifically, the radiographic imaging apparatus uses a property, such as absorption or transmission, of the object, through which radiation is transmitted.

Examples of the radiographic imaging apparatus may include a digital radiography (DR) apparatus, a fluoroscopy apparatus, a cardiography apparatus, a computed tomography (CT) apparatus, and a mammography apparatus. The radiographic imaging apparatus may be used to detect abnormalities, such as lesions, in the human body, to inspect the internal structure of an object or a part, or to scan luggage at airports, etc.

An operational principle of the radiographic imaging apparatus is as follows. The radiographic imaging apparatus emits radiation to an object, receives radiation transmitted through the object or directly transmitted through the surroundings of the object using a radiation detector, converts the received radiation into an electrical signal, reads out the electrical signal, and generates an image using the read electrical signal, thereby acquiring a radiographic image.

### SUMMARY

Exemplary embodiments may address at least the above problems and/or disadvantages and other disadvantages not described above. The exemplary embodiments are not required to overcome the disadvantages described above, and an exemplary embodiment may not overcome any of the problems described above.

One or more of exemplary embodiments provide a photon counting controller, a radiographic imaging apparatus, and a control method of the photon counting controller wherein input photons are rapidly counted to acquire a radiographic image.

One or more of exemplary embodiments also provide a photon counting controller, a radiographic imaging apparatus, and a control method of the photon counting controller wherein an electrical signal charged in a charger is rapidly discharged, thereby reducing a dead time needed for recharging.

One or more of exemplary embodiments also provide a photon counting controller, a radiographic imaging apparatus, and a control method of the photon counting controller wherein photons are rapidly counted to acquire a plurality of radiographic images.

In accordance with an aspect of an exemplary embodiment, a photon counting controller includes an amplification controller to charge an input electrical signal to amplify the input electrical signal and to discharge the charged electrical signal, a charge controller to control charge and discharge of the electrical signal of the amplification controller, and a measuring controller to compare voltage of the amplified electrical signal with critical voltage and to count photons based on a result of comparison, wherein the charge controller controls charge and discharge of the electrical signal of the amplification controller according to a received feedback signal.

The charge controller may include at least one resistor variable according to the feedback signal.

The charge controller may include a plurality of resistors configured to be connected to or disconnected from the amplification controller according to the feedback signal and may connect at least one of the resistors to the amplification controller in parallel to control charge and discharge of the electrical signal of the amplification controller.

The charge controller may apply current corresponding to the feedback signal to the amplification controller according to the feedback signal to control discharge of the electrical signal of the amplification controller.

In accordance with an aspect of an exemplary embodiment, a radiographic imaging apparatus includes a radiation emitting source to emit radiation to an object, a radiation detector to receive radiation transmitted through the object or directly reaching the radiation detector, to convert the received radiation into an electrical signal, and to output the converted electrical signal, a photon counter to charge the converted electrical signal to amplify the converted electrical signal, to discharge the charged electrical signal, to compare voltage of the amplified electrical signal with critical voltage, and to measure intensity of the radiation transmitted through the object based on a result of comparison, and a charge controller to control charge and discharge of the electrical signal of the photon counter, wherein the charge controller controls charge and discharge of the electrical signal of the photon counter according to a feedback signal.

In accordance with an aspect of an exemplary embodiment, a control method of a photon counting controller includes charging a charger with an input electrical signal and amplifying the input electrical signal, comparing voltage of the amplified electrical signal with critical voltage, and counting photons based on a result of comparison, wherein the control method further includes discharging the charged electrical signal according to a received feedback signal.

### BRIEF DESCRIPTION OF THE DRAWINGS

The and/or other aspects will become more apparent by describing certain exemplary embodiments, with reference to the accompanying drawings, in which:

FIG. 1 is a view showing construction of an exemplary embodiment of a photon counting controller;

FIGS. 2A and 2B are graphs illustrating an example of charge and discharge according to operation of a charge controller;

FIG. 3 is a view showing construction of an exemplary embodiment of a photon counting controller;

FIG. 4 is a circuit diagram of an exemplary embodiment of the photon counting controller;

FIG. 5 is a graph illustrating charge and discharge of a charger of the photon counting controller;

FIG. 6 is a view showing construction of an exemplary embodiment of a photon counting controller;

FIG. 7 is a circuit diagram of an exemplary embodiment of the photon counting controller;

FIG. 8 is a circuit diagram of an exemplary embodiment of a photon counting controller;

FIG. 9 is a view showing construction of an exemplary embodiment of a photon counting controller;

FIG. 10 is a circuit diagram of an exemplary embodiment of the photon counting controller;

FIG. 11 is a view showing construction of an exemplary embodiment of a measuring controller;

FIGS. 12, 13, and 14 are flowcharts showing various exemplary embodiments of a control method of the photon counting controller;

FIG. 15 is a front view showing an exemplary embodiment of a radiographic imaging apparatus;

FIG. 16 is a view showing construction of an exemplary embodiment of the radiographic imaging apparatus;

FIG. 17 is a view showing an exemplary embodiment of a radiation emitting source;

FIG. 18 is a view showing an exemplary embodiment of a radiation receiving panel;

FIGS. 19 and 20 are views showing exemplary embodiments of a radiation receiving panel and a photon counter; and

FIG. 21 is a flowchart showing an exemplary embodiment of a control method of the radiographic imaging apparatus.

### DETAILED DESCRIPTION

Certain exemplary embodiments are described in greater detail below with reference to the accompanying drawings.

In the following description, the same drawing reference numerals are used for the same elements even in different drawings. The matters defined in the description, such as detailed construction and elements, are provided to assist in a comprehensive understanding of exemplary embodiments. Thus, it is apparent that exemplary embodiments can be carried out without those specifically defined matters. Also, well-known functions or constructions are not described in detail since they would obscure exemplary embodiments with unnecessary detail.

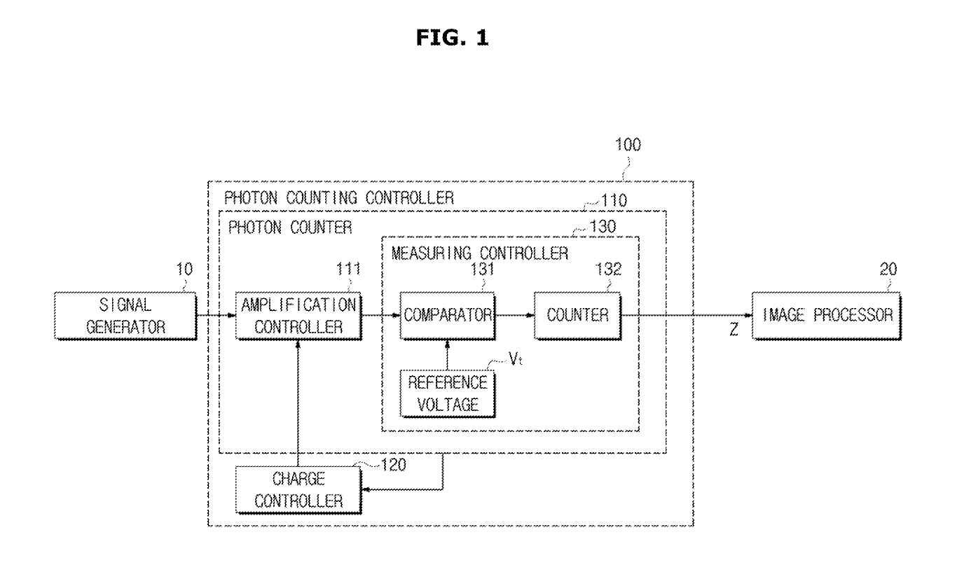

A photon counting controller will be described with reference to FIGS. 1 to 11.

FIG. 1 is a view showing construction of an exemplary embodiment of a photon counting controller.

A photon counting controller 100 may count photons based on an electrical signal x.

As shown in FIG. 1, the photon counting controller 100 may receive an electrical signal x from a signal generator 10 as an input signal.

The signal generator 10 may generate a predetermined electrical signal x, such as an electrical charge packet including a plurality of charges, and transmit the generated electrical signal x to the photon counter 110 according to a predetermined operation. For example, the signal generator 10 may be a radiation detector to receive radiation from the outside and to generate a predetermined electrical signal x corresponding to the received radiation.

The photon counting controller 100 may count photons based on the electrical signal generated by the signal generator 10 to generate a result signal z, output the result signal z, and transmit the result signal z to an image processor 20.

Specifically, the photon counting controller 100 may include the photon counter 110 and a charge controller 120.

The photon counter 110 may receive an electrical signal including information regarding photons, count the photons, and output a predetermined result signal corresponding to the counted result. Specifically, the photon counter 110 may charge and amplify the received electrical signal, compare voltage of the amplified electrical signal with predetermined critical voltage, count photons according to the result of comparison, and output a result signal. The electrical signal charged by the photon counter 110 may be discharged after a predetermined time.

The charge controller 120 may control charge and discharge of the electrical signal of the photon counter 110.

More specifically, the photon counter 110 may include an amplification controller 111 as shown in FIG. 1.

The amplification controller 111 may amplify the electrical signal x generated by the signal generator 10 and input to the amplification controller 111, output the amplified electrical signal of predetermined voltage, and transmit the amplified electrical signal to a measuring controller 130. The amplified electrical signal of the predetermined voltage may be used as a control signal to control the charge controller 120.

The amplification controller 111 may charge the electrical signal x while amplifying the electrical signal x. The charged electrical signal x may be discharged to charge a new electrical signal x. The amplification controller 111 may include a predetermined charger to charge the electrical signal x. For example, the charger may be a capacitor. The charger of the amplification controller 111 may express an electrical signal x, such as an electrical charge packet, transmitted to the amplification controller 111 as voltage while storing the electrical charge packet. The amplitude of the voltage charged in the charger may be proportional to the size of the electrical charge packet. In this way, the amplification controller 111 may recognize the received electrical signal x using the charger as voltage while charging the electrical signal x and amplify the input electrical signal x using the same.

Charge and discharge of the electrical signal x performed by the amplification controller 111 may be controlled by the charge controller 120 as shown in FIG. 1.

As shown in FIG. 1, the charge controller 120 may receive a feedback signal, such as an amplification signal or a control signal, and control charge and discharge of the photon counter 110 based on the received feedback signal. Specifically, the charge controller 120 may control charge and discharge of the electrical signal x performed by the amplification controller 111 of the photon counter 110 according to the feedback signal.

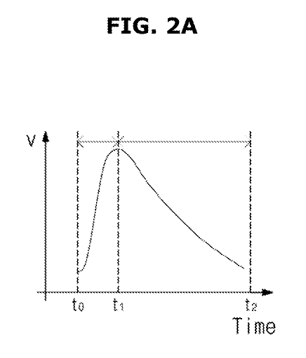

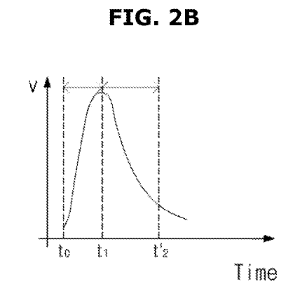

FIG. 2 is a graph illustrating an example of charge and discharge according to operation of the charge controller.

As shown in FIG. 2A, the amplification controller 111 charges an electrical signal x input for a predetermined charge time (t0 to t1) in the charger and discharges the charged electrical signal for a predetermined discharge time (t1 to t2). That is, the amplification controller 111 stores an input electrical signal x in the charger for a predetermined time and removes the electrical signal x stored in the charger for a predetermined time.

This will be described in more detail hereinafter.

In a case in which an input electrical signal x is a predetermined electrical charge packet including a plurality of charges, the electrical charge packet is continuously transmitted to the charger of the amplification controller 111 for a predetermined time, i.e., a predetermined charge time (t0 to t1) and the continuously transmitted electrical charge packet accumulates in the charger to charge the charger. The electrical charge packet may be charged in the form of voltage as described above. In a case in which the electrical charge packet is continuously introduced into the charger, therefore, voltage increases over time (t0 to t1) as shown in FIG. 2A. When the electrical charge packet is charged into the charger to a predetermined level or more, the electrical charge packet charged in the charger of the amplification controller 111 is discharged for a predetermined discharge time (t1 to t2).

As the electrical charge packet charged in the charger of the amplification controller 111 is discharged, the charger may be charged with a newly applied electrical charge packet. That is, in a case in which the charger, in which a predetermined electrical signal, such as an electrical charge packet, is stored, is to be charged with a new electrical signal, such as a new electrical charge packet, it may be needed to discharge an electrical signal, such as an electrical charge packet, previously charged in the charger. Otherwise, the charger of the amplification controller 111 cannot store a newly transmitted electrical charge packet. Since the electrical charge packet is discharged for the predetermined discharge time (t1 to t2), the charger of the amplification controller 111 may store a new electrical signal after some time lapses after the storing of a previous electrical signal is finished, i.e., after a discharge time (t1 to t2) lapses.

Since a predetermined time, i.e., a discharge time (t1 to t2), needs to elapse for the amplification controller 111 to store the new electrical signal, the measuring controller 130, which receives an amplified signal from the amplification controller 111, may perform a new photon counting operation after a predetermined time, i.e., a discharge time (t1 to t2). Consequently, a dead time corresponding to the discharge time (t1 to t2) may be needed between successive photon counting operations.

The charge controller 120 controls an electrical signal x stored in the charger of the amplification controller 111, i.e., an electrical charge packet charged in the charger, to be rapidly discharged, thereby minimizing the dead time.

The charge controller 120 will be described hereinafter.

Specifically, as shown in FIG. 2B, the charge controller 120 may control an electrical signal, i.e., an electrical charge packet, stored in the charger of the amplification controller 111 to be rapidly discharged to shorten the discharge time (t1 to t2), thereby minimizing the dead time.

In an exemplary embodiment, the charge controller 120 may control a discharge time of the charger using at least one of a variable resistor, a passive component, or an active component.

An exemplary embodiment of the charge controller 120 will be described hereinafter.

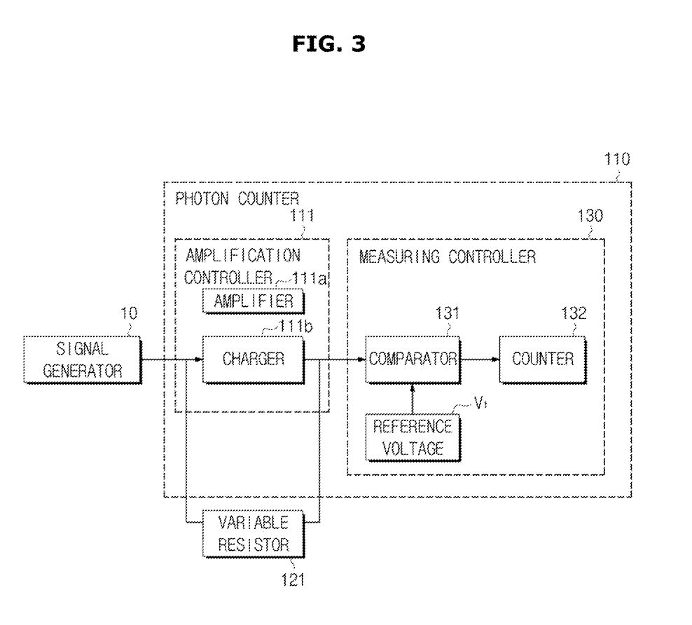

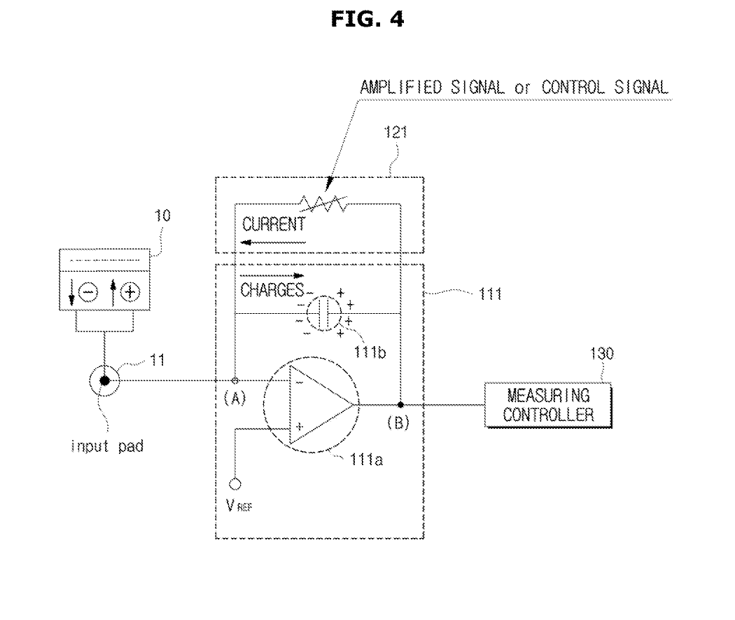

FIG. 3 is a view showing construction of an exemplary embodiment of a photon counting controller and FIG. 4 is a circuit diagram of an exemplary embodiment of the photon counting controller.

As shown in FIGS. 3 and 4, an amplification controller 111 of a photon counting controller 100 may include an amplifier 111a and a charger 111b. The amplifier 111a and the charger 111b may be connected to each other in parallel as shown in FIG. 4. The charge controller 120 may include at least one variable resistor 121 connected to the charger 111b in parallel.

The amplifier 111a of the amplification controller 111 may amplify variation of input current or voltage such that a signal having larger variation may be output. Specifically, in a case in which predetermined change of voltage or current occurs at terminal (A) of FIG. 4, the amplifier 111a may sensitively respond to the change in voltage or current such that voltage or current having larger variation may be generated at terminal (B) of FIG. 4. The amplifier 111a may be, for example, an operational amplifier.

As shown in FIG. 4, a positive (+) input terminal of the amplifier 111a may be connected to first external reference voltage V_{REF} and a negative (−) input terminal of the amplifier 111a may be connected to an input pad 11, to which an electrical signal generated by the signal generator 10 is input.

As shown in FIG. 4, the charger 111b may be connected to the amplifier 111a in parallel. The charger 111b may be, for example, a capacitor.

The charger 111b may be connected to the input pad 11, to which an electrical signal is input. According to exemplary embodiments, the charger 111b may receive negative charges input through the input pad 11 such that the charger 111b may be charged with the received negative charges. That is, as shown in FIG. 4, the left side of the charger 111b may be charged with negative charges. Consequently, the right side of the charger 111b may be charged with positive charges. In this case, current may flow from the charger 111b to the input part 11.

A variable resistor 121, as an example of the charge controller 120, may receive an external feedback signal, such as an amplified electrical signal or an additional control signal and change a resistance value according to the received feedback signal, such as the amplified electrical signal or the additional control signal, to control charge and discharge of the charger 111b. The amplified electrical signal may be an electrical signal amplified by the amplification controller 111. The additional control signal may be a control signal generated by an external processing unit or the measuring controller 130.

The variable resistor 121 may increase or decrease the resistance value according to the external feedback signal to control charge and discharge of the charger 111b. For example, in a case in which the charger 111b needs to be charged with an electrical signal, such as an electrical charge packet, the variable resistor 121 increases the resistance value such that an electrical signal, such as charges, transmitted from the input pad 11 is blocked by the variable resistor 121 and is passed to the charger 111b. Consequently, the charger 111b is charged with the electrical signal in the form of voltage as shown in FIGS. 2A and 2B.

In a case in which discharge of the charger 111b is needed, the variable resistor 121 reduces the resistance value such that the electrical signal, such as the charges, transmitted from the input pad 11 is passed to the variable resistor 121. In a case in which the resistance value of the variable resistor 121 is small, the electrical signal, such as the charges, charged in the charger 111b discharges into the variable resistor 121 such that the electrical signal flows to terminal (B). As a result, the charges charged in charger 111b may be rapidly discharged.

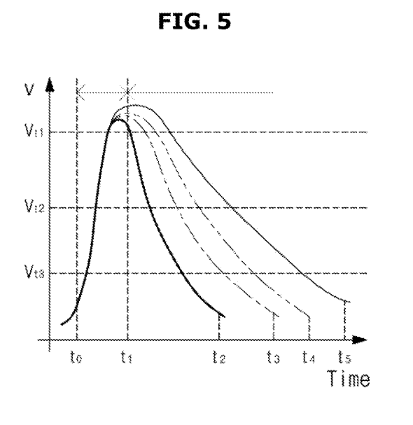

FIG. 5 is a graph illustrating charge and discharge of the charger of the photon counting controller.

When the variable resistor 121 has a relatively large resistance value, for example, the maximum resistance value, when charges are introduced to a circuit from the signal generator 10 through the input pad 11, the charges are introduced into the charger 111b such that the charger 111b is charged with the charges. The variable resistor 121 is connected to the charger 111b in parallel. When the resistance value of the variable resistor 121 is large, therefore, loss of the charges is prevented to generate a voltage signal having the maximum amplitude. As a result, voltage charge increases as shown in FIG. 5.

When the voltage exceeds predetermined critical voltage, such as first critical voltage Vt1, the resistance value of the variable resistor may decrease according to a feedback signal. The feedback signal may be an amplified electrical signal. More specifically, the feedback signal may be voltage of the amplified electrical signal. That is, when the voltage of the amplified electrical signal exceeds to a predetermined level, the resistance value of the variable resistor 121 may decrease. As the result of decrease of the resistance value, the charges charged in the charger 111b are discharged and flow through the variable resistor 121. As shown in FIG. 5, since the charges charged in the charger 111b may more easily flow through the variable resistor 121 as the resistance value of the variable resistor 121 decreases, the charges may be more rapidly discharged from the charger 111b. That is, a discharge time decreases in proportion to decrease of the resistance value. In other words, a discharge time value (t1 to t2) when the resistance value is small may be much smaller than discharge times (t1 to t3, t4 or t5) when the resistance value is larger. Consequently, the variable resistor 121 may control the charger 111b to be rapidly discharged according to the external feedback signal, thereby reducing the dead time.

An exemplary embodiment of the charge controller 120 will be described hereinafter.

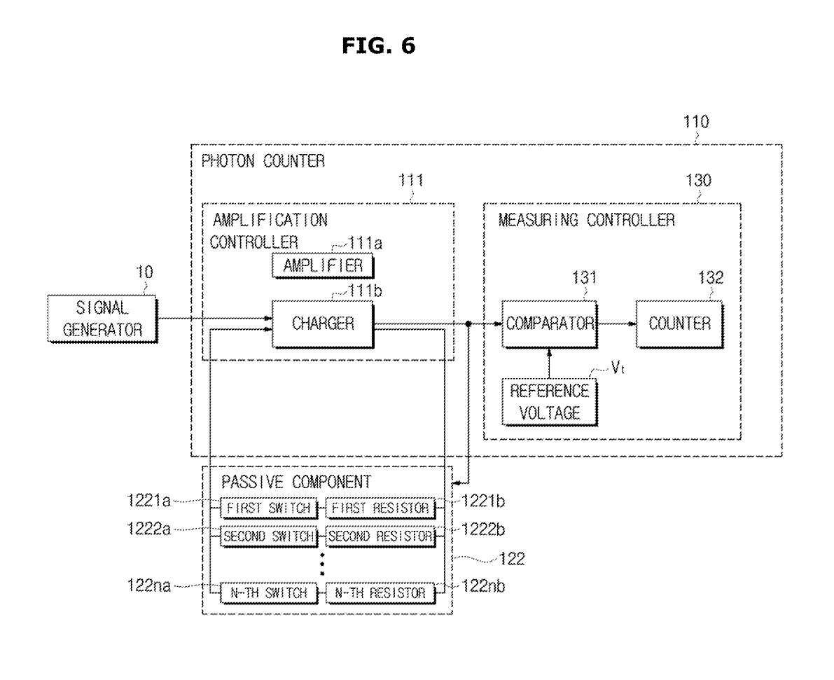

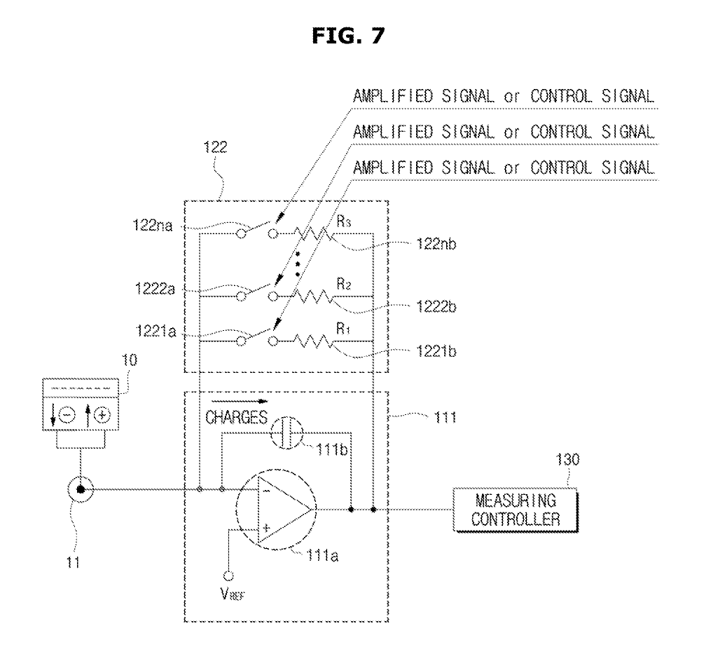

FIG. 6 is a view showing construction of an exemplary embodiment of a photon counting controller and FIG. 7 is a circuit diagram of an exemplary embodiment of the photon counting controller.

As shown in FIG. 6, the charge controller 120 may include a passive component 122.

As shown in FIGS. 6 and 7, the passive component 122 may be connected to a charger 111b in parallel.

Specifically, as shown in FIGS. 6 and 7, the passive component 122 may include first and second to Nth resistors 1221b and 1222b to 122nb. The resistors 1221b to 122nb of the passive component 122 may be connected to the charger 111b in parallel. In addition, the resistors 1221b to 122nb may be connected to each other in parallel. According to exemplary embodiments, some of the resistors 1221b to 122nb may be connected to each other in parallel and some of the resistors 1221b to 122nb may be connected to each other in series.

The passive component 122 may include first and second to Nth switches 1221a and 1222a to 122na respectively connected to the resistors 1221b and 1222b to 122nb.

The switches 1221a to 122na of the passive component 122 may be electrically connected to or disconnected from the respective resistors 1221b to 122nb according to an external feedback signal, such as an amplified electrical signal or a control signal to change a resistance value of the passive component 122. Specifically, the passive component 122 may be electrically connected to an amplification controller 111 to receive an amplified electrical signal output from the amplification controller 111 and control the switches 1221a to 122na of the passive component 122 according to the received electrical signal to change the resistance value of the passive component 122.

For example, in a case in which the charger 111b needs to be charged with an electrical signal, such as an electrical charge packet, some or all of the switches 1221a to 122na of the passive component 122 may be closed to increase the resistance value of the passive component 122 or opened such that the switches 1221a to 122na are not electrically connected to the respective resistors 1221b to 122nb. Consequently, an electrical signal, such as charges, transmitted from an input pad 11 is blocked by the passive component 122 and only flows to the charger 111b based on the large resistance value or electrical disconnection of the passive component 122. As a result, the charger 111b is charged with the electrical signal. As shown in FIG. 5, therefore, voltage of the charger 111b increases. Of course, some of the charges may flow to the respective resistors 1221b to 122nb even when the resistance value of the passive component 122 is large. However, such flow of some of the charges has little influence.

In a case in which the charger 111b is discharged, some of the switches 1221a to 122na are opened and some of the switches 1221a to 122na are closed to decrease the resistance value of the passive component 122. In a case in which the resistance value of the passive component 122 is small, an electrical signal, such as charges, transmitted from the input pad 11 may flow to the passive component 122. The electrical signal, such as the charges, charged in the charger 111b may flow to terminal (B) through the passive component 122. Consequently, the electrical signal charged in the charger 111b may be discharged.

The resistance value of the passive component 122 may be decided based on operations of the switches 1221a to 122na and resistance values of the resistors 1221b to 122nb connected to the switches 1221a to 122na. For example, in a case in which the charger 111b needs to be discharged, one of the switches 1221a to 122na of the passive component 122 connected to the resistor having the minimum resistance value may be opened to electrically connect the resistor having the minimum resistance value to the charger 111b such that the charges charged in the charger 111b may be rapidly discharged.

An exemplary embodiment of the charge controller 120 will be described hereinafter.

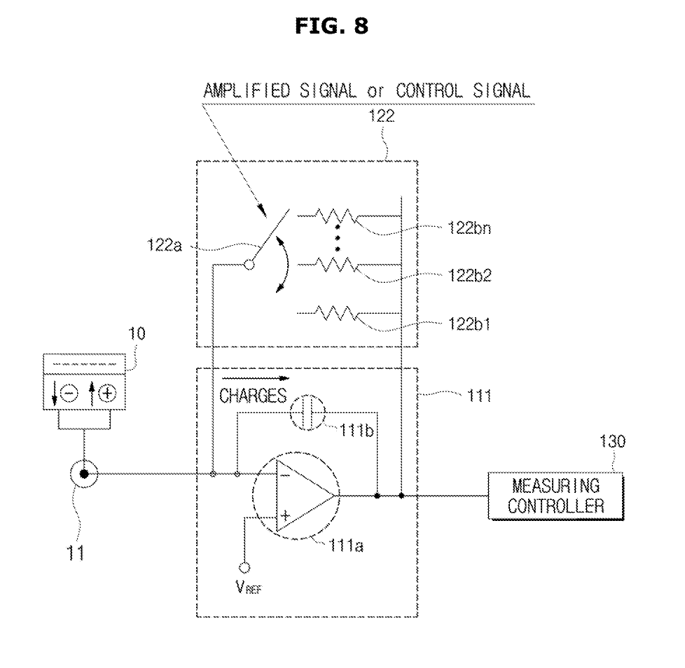

FIG. 8 is a circuit diagram of an exemplary embodiment of a photon counting controller.

As shown in FIG. 8, a passive component 122 may include a plurality of resistors 122b1 and 122b2 to 122bn and a switch 122a to perform switching among the resistors 122b1 to 122bn.

The resistors 122b1 to 122bn may be connected to a charger 111b of an amplification controller 111 according to operation of the switch 122a. The resistors 122b1 to 122bn may have different resistance values.

The switch 122a may perform electrical connection to or disconnection from at least one of the resistors 122b1 to 122bn according to an external feedback signal, such as an amplified electrical signal or a control signal, to change a resistance value of the passive component 122.

In a case in which the charger 111b needs to be charged with an electrical signal, such as an electrical charge packet, the switch 122a may perform parallel connection between one having the maximum resistance value of the resistors 122b1 to 122bn and the charger 111b or disconnection between any one of the resistors 122b1 to 122bn and the charger 111b such that an electrical signal from a signal generator 10 may be transmitted only to the charger 111b and thus the charger 111b is charged with the electrical signal.

On the other hand, in a case in which the charger 111b needs to be discharged, the switch 122a may perform parallel connection between one of the resistors having the minimum resistance value of the resistors 122b1 to 122bn and the charger 111b such that current may also flow to the resistor having the minimum resistance value and thus the electrical signal, i.e., charges, charged in the charger 111b is discharged.

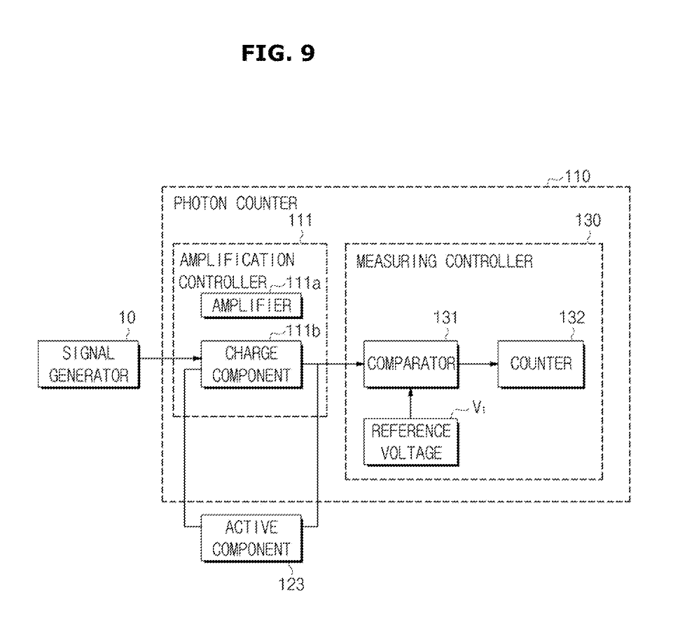

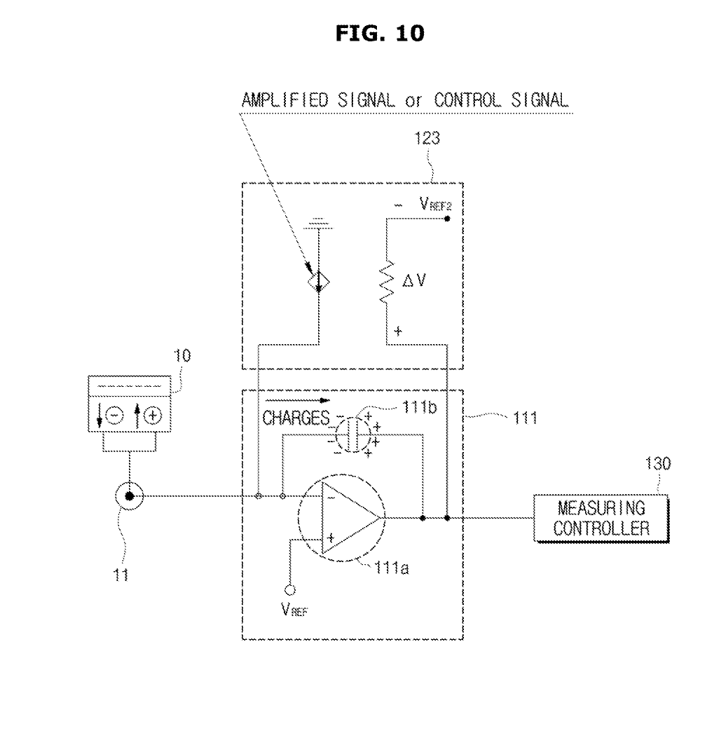

FIG. 9 is a view showing construction of an exemplary embodiment of a photon counting controller and FIG. 10 is a circuit diagram of an exemplary embodiment of the photon counting controller.

As shown in FIGS. 9 and 10, a charge controller 120 of a photon counting controller 100 may include an active component 123. The active component 123 may be connected to an amplification controller 111, specifically a charger 111b, in parallel.

In an exemplary embodiment, the active component 123 may receive a feedback signal, such as an amplified electrical signal or a control signal, and apply predetermined current to the charger 111b according to the received feedback signal to discharge the charger 111b.

As shown in FIG. 10, in a case in which an electrical signal output from a signal generator 10 in response to sensing of external radiation is negative (−) charges, the negative charges may be transmitted to the charger 111b through an input pad 11. The charger 111b may be charged with the negative charges. As a result, in FIG. 10, the left side of the charger 111b is charged as a cathode and the right side of the charger 111b is charged as an anode.

When an electrical signal is amplified through an amplifier 111a and the charger 111b, the active component 123 may receive the amplified electrical signal or voltage of the amplified electrical signal and supply predetermined current to the amplification controller 111 according to the received voltage of the amplified electrical signal.

For example, the active component 123 may supply current corresponding to a difference between the voltage of the amplified electrical signal and original voltage to the amplification controller 111.

The active component 123 may compare the voltage of the amplified electrical signal with predetermined second reference voltage V_{REF2} and supply predetermined current to the amplification controller 111 according to the result of comparison. Specifically, the active component 123 may calculate a difference ΔV between the voltage of the amplified electrical signal and the predetermined second reference voltage V_{REF2} and supply predetermined current to an input terminal of the amplification controller 111 according to the calculated difference ΔV between the voltage of the amplified electrical signal and the predetermined second reference voltage V_{REF2}. The current supplied to the amplification controller 111 reaches the charger 111b and the negative charges stored in the charger 111b are discharged according to the current supplied to the amplification controller 111. In other words, the negative charges may flow from the charger 111b to the active component 123 such that the negative charges stored in the charger 111b are discharged.

On the other hand, in a case in which the charger 111b is charged with positive charges, the active component 123 may supply negative charges to the charger 111b such that current flows from the charger 111b to the active component 123 to discharge the charger 111b.

The active component 123 may rapidly supply current or negative charges to the charger 111b to rapidly discharge the charger 111b.

As described above, the charge controller 120 may change a resistance value of the charge controller 120 or apply current or negative charges to the charger 111b to reduce a discharge time of the charger 111b, thereby reducing a dead time during photon counting.

As described above, the amplification controller 111 of the photon counter 110 may output an amplified electrical signal. As shown in FIGS. 3, 4, and 6 to 10, the output electrical signal may be transmitted to the charge controller 120. The charge controller 120 may control charge and discharge of the electrical signal performed by the amplification controller 111 according to the output amplified electrical signal.

For example, in a case in which the amplified electrical signal transmitted to the charge controller 120 is greater than predetermined voltage, the charge controller 120 may decrease the resistance value of the variable resistor 121 or operate the switches 1221a to 122na (FIG. 6) or the switch 122a (FIG. 8) such that the resistor having the small resistance value is electrically connected to the amplification controller 111 to rapidly discharge the electrical signal from the amplification controller 111. In addition, in a case in which the amplified electrical signal transmitted to the charge controller 120 is greater than the predetermined voltage, the charge controller 120 may apply predetermined current to the amplification controller 111 to rapidly discharge the electrical signal from the amplification controller 111.

On the other hand, in a case in which the amplified electrical signal transmitted to the charge controller 120 is less than the predetermined voltage, the charge controller 120 may decrease the resistance value of the variable resistor 121 or operate the switches 1221a to 122na (FIG. 6) or the switch 122a (FIG. 8) such that the resistor having the large resistance value is electrically connected to the amplification controller 111 to rapidly charge the amplification controller 111 with the electrical signal. The charge controller 120 may interrupt application of predetermined current to the amplification controller 111 to rapidly charge the amplification controller 111 with the electrical signal.

The measuring controller 130 will be described hereinafter.

As shown in FIG. 1, the photon counter 110 may further include the measuring controller 130. The measuring controller 130 may receive an electrical signal amplified by the amplification controller 111, count photons using the received amplified electrical signal, and output a result signal.

Specifically, the measuring controller 130 may compare voltage of the electrical signal amplified by the amplification controller 111 with a predetermined reference voltage Vₜ and count photons according to the result of comparison. In a case in which the photon counting controller 10 is applied to a radiographic imaging apparatus, the measuring controller 130 may compare voltage of the amplified electrical signal with the predetermined reference voltage and measure intensity of radiation according to the result of comparison.

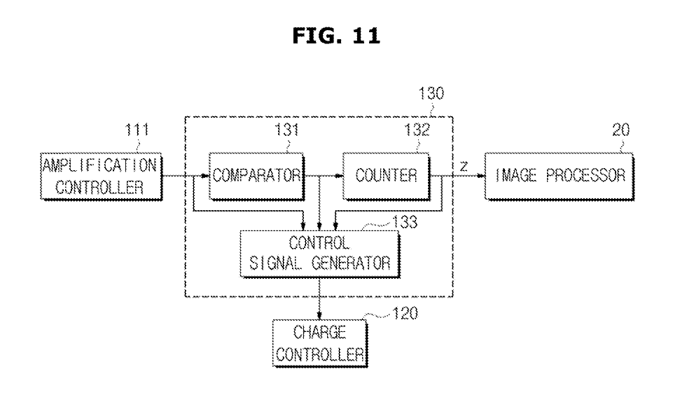

FIG. 11 is a view showing construction of an exemplary embodiment of a measuring controller.

Specifically, as shown in FIGS. 1 and 11, a measuring controller 130 may include a comparator 131 and a counter 132.

The comparator 131 may compare an electrical signal amplified by an amplification controller 111 with at least one reference energy level to determine whether the amplified electrical signal is greater or less than the reference energy and output a signal based on the comparison and determination result. In an exemplary embodiment, the comparator 131 may compare voltage of an electrical signal amplified by the amplification controller 111 with at least one reference voltage Vₜ corresponding to at least one reference energy to determine whether the voltage of the electrical signal is greater or less than the reference voltage Vₜ.

The reference voltage used by the comparator 131 for comparison may be predefined by a user or a system designer. The reference voltage may be decided according to system settings. Moreover, the reference voltage may be changed by the user or the system as needed.

Although not shown, the measuring controller 130 may further include a database to store the reference energy or the reference voltage. The comparator 131 may read the database storing the reference energy or the reference voltage, retrieve predetermined reference voltage or reference energy from the database according to user selection or system setting, and compare the electrical signal amplified by the amplification controller 111 with the retrieved predetermined reference energy.

In an exemplary embodiment, the comparator 131 may generate and output a predetermined binary signal according to the comparison and determination result between the amplified electrical signal and the reference energy. For example, upon determining that voltage of the electrical signal is equal to or greater than the reference voltage, the comparator 131 may output a signal of 1. On the other hand, upon determining that voltage of the electrical signal is less than the reference voltage, the comparator 131 may output a signal of 0. A signal, such as a binary signal, regarding the comparison and determination result output from the comparator 131 is transmitted to the counter 132.

The counter 132 counts photons equal to or greater than the reference energy according to the signal received from the comparator 131 and outputs a result signal z regarding photon counting. In a radiographic imaging apparatus, the result signal z regarding photon counting may be used to measure intensity of radiation. In an exemplary embodiment, the counter 132 may count only a signal of 1 output from the comparator 131 to count the number of photons greater than the reference energy.

In an exemplary embodiment, the measuring controller 130 may further include a control signal generator 133.

The control signal generator 133 may sense or receive at least one signal from among an amplified electrical signal input to the comparator 131, a signal according to a comparison and determination result output from the comparator 131, and a result signal output from the counter 132, generate a predetermined control signal according to the sensed or received signal, and transmit the generated control signal to the charge controller 120.

For example, in a case in which the comparator 131 outputs a signal according to a comparison and determination result, the control signal generator 133 may sense the signal according to the comparison and determination result and determine that comparison and determination has been ended according to sensing of the signal. Upon determining that the comparison and determination has been ended, the control signal generator 133 may generate a control signal to control the charge controller 120 to discharge an electrical signal charged in the amplification controller 111 and transmit the generated control signal to the charge controller 120. The charge controller 120 may decrease the resistance value of the variable resistor 121 or operate at least one of the switches 1221a to 122na (FIG. 6) or the switch 122a (FIG. 8) according to the received control signal such that one resistor having a predetermined resistance value is electrically connected to the amplification controller 111 or apply predetermined current to the amplification controller 111, specifically the charger 111b, to rapidly discharge the electrical signal from the amplification controller 11.

The photon counted result signal z may be output from the counter 132 to the outside through an output pad of the photon counting controller 100. The result signal z output from the photon counting controller 100 may be transmitted to, for example, the image processor 20. The image processor 20 may generate an image having predetermined reference energy according to the number of photons equal to or greater than the reference energy.

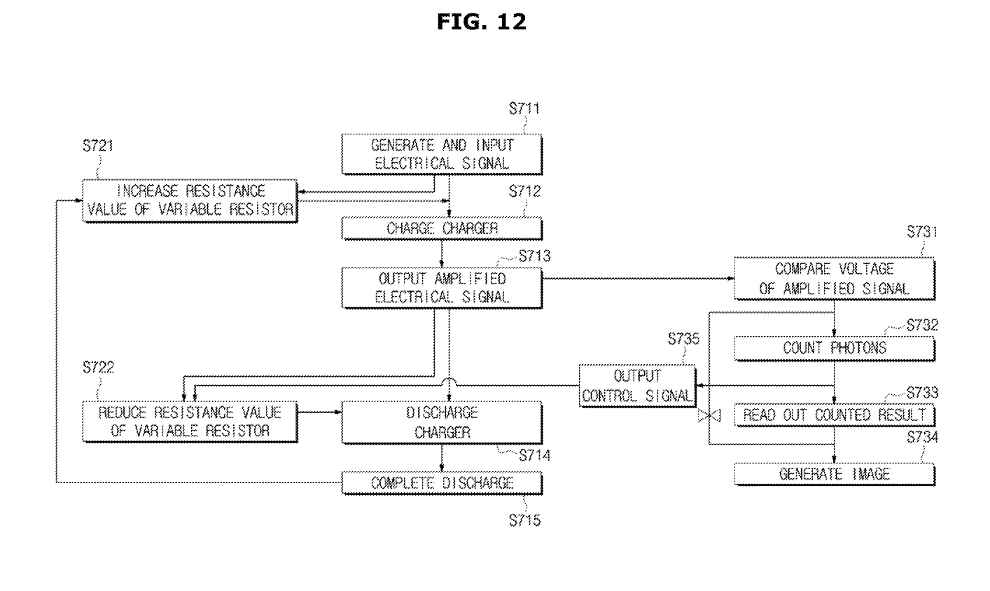

Hereinafter, various exemplary embodiments of a control method of the photon counting controller will be described with reference to FIGS. 12 to 14.

FIG. 12 is a flowchart showing an exemplary embodiment of a control method of the photon counting controller.

Referring to FIG. 12, an electrical signal x generated by the signal generator 10 is input to the photon counting controller 100 (operation S711). The input electrical signal may be transmitted to the amplification controller 111.

The resistance value of the variable resistor 121 of the charge controller 120 is changed to the maximum value such that the charger 111b of the amplification controller 111 is charged with the electrical signal transmitted to the amplification controller 111 (operation S721). The variable resistor 121 may be connected to the amplification controller 111 in parallel as shown in FIGS. 3 and 4.

As the resistance value of the variable resistor 121 is changed to the maximum value, the electrical signal does not flow or minimally flows through the variable resistor 121. As a result, the entirety or most of the electrical signal is transmitted to the charger 111b to charge the charger 111b (operation S712). The electrical signal transmitted to the charger 111b may be expressed as voltage while the electrical signal is charged in the charger 111b.

The electrical signal may be amplified while passing through the amplification controller 111 and the amplified electrical signal may be output and transmitted to the measuring controller 130 (operation S713). In addition, the amplified electrical signal may be transmitted to the charge controller 120. The amplified electrical signal transmitted to the charge controller 120 may function as a control signal to control the charge controller 120.

The measuring controller 130 compares voltage of the amplified electrical signal with reference voltage. The reference voltage may be decided by a user or system setting. The reference voltage may be varied as needed (operation S731).

The measuring controller 130 performs photon counting according to the result of comparison between the amplified electrical signal and the reference voltage (operation S732). Specifically, the measuring controller 130 may count photons equal to or greater than reference energy and output a result signal z regarding photon counting.

Consequently, photon counting may be performed.

A signal regarding the result of comparison and a result signal z regarding photon counting may be output at operations S731 and S732, respectively. The output signal regarding the result of comparison or the output result signal z regarding photon counting may be transmitted to the charge controller 120 as a control signal of the charge controller 120. On the other hand, the signal regarding the result of comparison or the result signal z regarding photon counting may be sensed or received by the control signal generator 133. The control signal generator 133 may generate and output a predetermined control signal according to the sensed or received signal regarding the result of comparison or the sensed or received result signal z regarding photon counting (operation S735). The output control signal may be transmitted to the charge controller 120.

The charge controller 120 receives the amplified electrical signal, the signal regarding the result of comparison, the result signal z regarding photon counting, or the control signal generated by the control signal generator 133 and changes the resistance value of the variable resistor according to the received signal regarding the result of comparison, the received result signal z regarding photon counting, or the received control signal generated by the control signal generator 133 (operation S722). The charge controller 120 may change the resistance value of the variable resistor 121 to minimize the resistance value of the variable resistor 121.

When the resistance value of the variable resistor is the minimum, the electrical signal charged in the charger 111b may flow through the variable resistor. Consequently, the electrical signal charged in the charger 111b is discharged (operation S714).

In a case in which a predetermined time elapses, discharge is completed, or the residue of the electrical signal in the charger 111b is equal to or less than a reference residue value (operation S715), the variable resistor of the charge controller 120 may be changed to the maximum again to charge the charger 111b with the electrical signal again (operation S721 and S712).

When photon counting is performed and a result signal z regarding photon counting is output (operation S732), the output result signal z may be temporarily or non-temporarily stored in an additional storage space. The result signal z temporarily or non-temporarily stored in the additional storage space may be read out by an additional image processing device, such as the image processor 20 (operation S733). As needed, after the result signal z is read out, the control signal generator 133 may generate and output a predetermined control signal for the charge controller 120 in response to the readout of the result signal z (operation S735). An image corresponding to the read result signal may be generated according to the read result signal (operation S734).

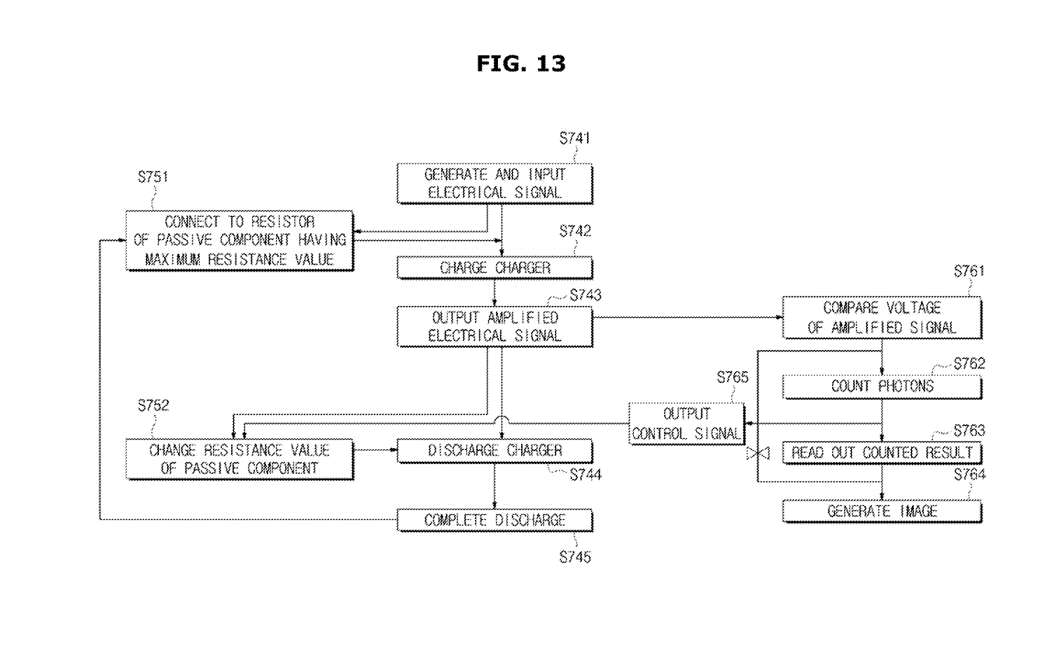

FIG. 13 is a flowchart showing an exemplary embodiment of a control method of the photon counting controller.

Referring to FIG. 13, an electrical signal x generated by the signal generator 10 is input to the photon counting controller 100 in the same manner as in the above description. The input electrical signal may be transmitted to the amplification controller 111 of the photon counting controller 100 (operation S741).

At least one of the resistors 1221b to 122nb included in the passive component 122 of the charge controller 120 may be selected (operation S751). The resistors 1221b to 122nb included in the passive component 122 of the charge controller 120 may be connected to the charger 111b of the amplification controller 111 in parallel as shown in FIGS. 6 to 8.

In this case, one of the resistors 1221b to 122nb having the maximum resistance value may be selected according to exemplary embodiments. Such selection may be performed according to on-off of at least one of the switches 1221a to 122na or switching of the switch 122a.

As one of the resistors 1221b to 122nb of the passive component 122 having the maximum resistance value is selected, the electrical signal does not flow or minimally flows through the passive component 122. As a result, the entirety or most of the electrical signal x is transmitted to the charger 111b of the amplification controller 111 to charge the charger 111b (operation S742).

The electrical signal may be amplified while passing through the amplification controller 111 and the amplified electrical signal may be output and transmitted to the measuring controller 130 or the charge controller 120 (operation S743). The amplified electrical signal transmitted to the charge controller 120 may function as a control signal to control the charge controller 120.

The measuring controller 130 may compare voltage of the amplified electrical signal with reference voltage and output a signal regarding the result of comparison in the same manner as in the above description (operation S761). The signal regarding the result of comparison may be transmitted to the charge controller 120 or may be sensed or received by the control signal generator 133. The control signal generator 133 may generate and output a control signal for the charge controller 120 according to the signal regarding the result of comparison and transmit the output control signal to the charge controller 120 (operation S765).

The measuring controller 130 may perform photon counting according to the result of comparison between the amplified electrical signal and the reference voltage and output a result signal z regarding photon counting (operation S762). The result signal z may also be transmitted to the charge controller 120 or may also be sensed or received by the control signal generator 133 (operation S765).

The output result signal z may be read out by the image processor 20 (operation S763). The image processor 20 may generate a predetermined image based on the read result signal z (operation S764). Meanwhile, when the result signal is read out by the image processor 20, the control signal generator 133 may generate and output a predetermined control signal for the charge controller 120 (operation S765).

The charge controller 120 may receive the amplified electrical signal, the signal regarding the result of comparison, the result signal z regarding photon counting, or the control signal generated by the control signal generator 133 and change the resistance value of the passive component 122 according to the received signal regarding the result of comparison, the received result signal z regarding photon counting, or the received control signal generated by the control signal generator 133 (operation S752). For example, one of the resistors 1221b to 122nb of the passive component 122 having the minimum resistance value may be selected to change the resistance value of the passive component. According to exemplary embodiments, one of the resistors 1221b to 122nb may be selected or two or more of the resistors 1221b to 122nb may be selected.

When the resistance value of the passive component 122 is changed, the electrical signal charged in the charger 111b may flow through the passive component 122. Consequently, the electrical signal charged in the charger 111b may be discharged (operation S744).

In a case in which a predetermined time elapses, discharge is completed, or the residue of the electrical signal in the charger 111b is equal to or less than a reference residue (operation S745), the resistance value of the passive component 122 returns to the original (large) value to charge the charger 111b of the amplification controller 111 with the electrical signal again (operation S751 and S742).

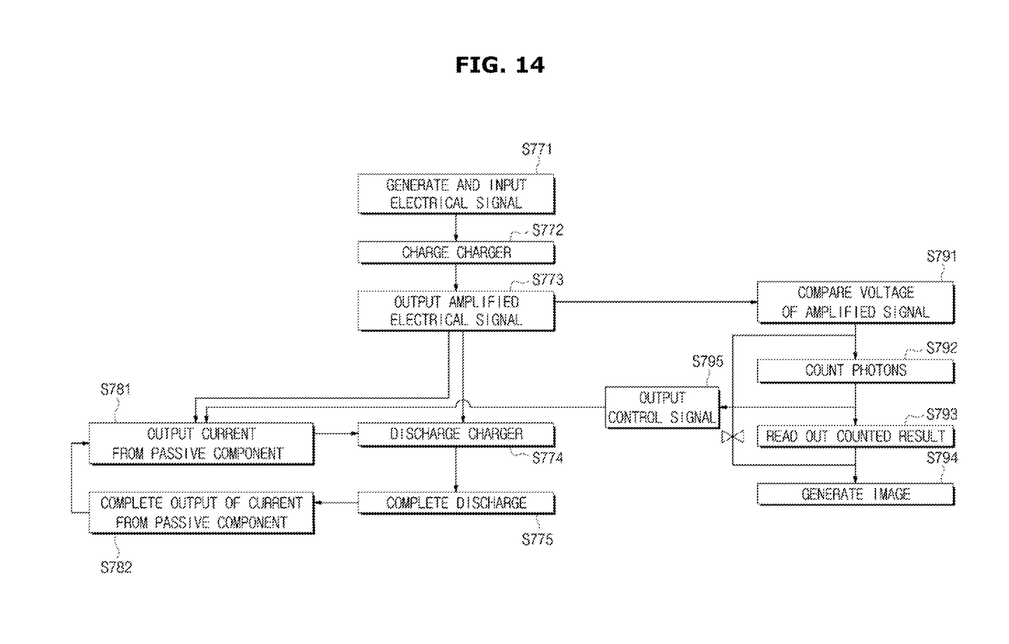

FIG. 14 is a flowchart showing an exemplary embodiment of a control method of the photon counting controller.

Referring to FIG. 14, the signal generator 10 generates an electrical signal x. The generated electrical signal x may be an electrical charge packet. Moreover, the electrical signal x may include negative charges. The electrical signal generated by the signal generator 10 may be transmitted to the amplification controller 111 of the photon counting controller 100 (operation S771). The electrical signal x transmitted to the amplification controller 111 is applied to the charger 111b of the amplification controller 111 to charge the charger 111b until voltage of the charger 111b reaches a predetermined voltage (operation S772). Meanwhile, the electrical signal x may be amplified while passing through the amplification controller 111. The amplified electrical signal may be output and transmitted to the measuring controller 130 or the charge controller 120 (operation S773). The amplified electrical signal transmitted to the charge controller 120 may function as a control signal to control the charge controller 120.

The measuring controller 130 may compare voltage of the amplified electrical signal with reference voltage and output a signal regarding the result of comparison in the same manner as in the above description (operation S791) and transmit the signal regarding the result of comparison to the charge controller 120 or the counter 132 of the measuring controller 130. The measuring controller 130, specifically the counter 132, may perform photon counting according to the result of comparison between the amplified electrical signal and the reference voltage and output a result signal z regarding photon counting (operation S792).

The image processor 20 may read out the result signal z (operation S793) and generate a predetermined image based on the read result signal z (operation S794).

In an exemplary embodiment, at least one signal between the signal regarding the result of comparison and the result signal z may function as a control signal to control the charge controller 120. In addition, at least one signal between the signal regarding the result of comparison and the result signal z may be sensed or received by the control signal generator 133. The control signal generator 133 may generate and output a control signal to control the charge controller 120 based on the sensed or received signal regarding the result of comparison and the sensed or received result signal z (operation S795). Meanwhile, when the result signal is read out by the image processor 20, the control signal generator 133 may generate and output a predetermined control signal for the charge controller 120 as described above.

The charge controller 120 may receive the amplified electrical signal, the signal regarding the result of comparison, the result signal z regarding photon counting, or the control signal generated by the control signal generator 133 and may operate according to the received signal. The charge controller 120 may be the active component 123. In an exemplary embodiment, the active component 123 may calculate a difference ΔV between the voltage of the amplified electrical signal and the predetermined second reference voltage V_{REF2} and output and supply predetermined current to the amplification controller 111 according to the calculated difference ΔV between the voltage of the amplified electrical signal and the predetermined second reference voltage V_{REF2} (operation S781).

The output predetermined current reaches the charger 111b of the amplification controller 111 to discharge the electrical signal, including the negative charges, stored in the charger 111b (operation S774).

In a case in which discharge of the electrical signal in the charger 111b is completed (operation S755), the active component 123 may interrupt output of the current (operation S782). Alternatively, the active component 123 may interrupt output of the current after a predetermined time elapses to complete discharge of the charger 111b. Upon completion of the discharge, the charger 111b may be charged with a newly input electrical signal.

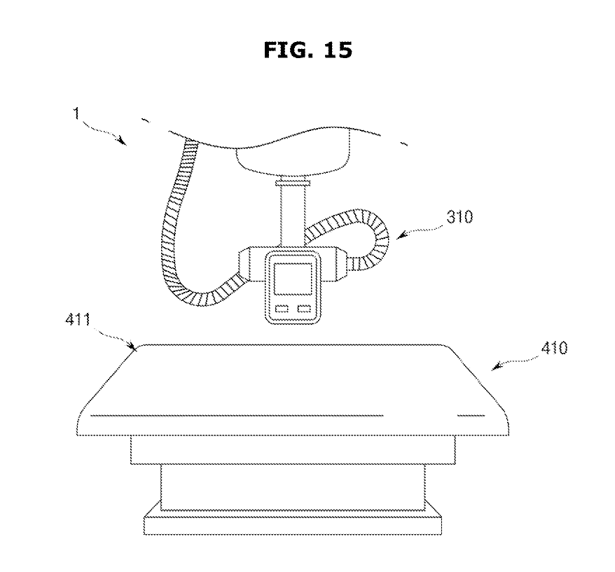

Hereinafter, a radiographic imaging apparatus will be described with reference to FIGS. 15 to 20.

FIG. 15 is a front view showing an exemplary embodiment of a radiographic imaging apparatus.

As shown in FIG. 15, a radiographic imaging apparatus may be a digital radiography apparatus 1. Hereinafter, a digital radiography apparatus will be described as an exemplary embodiment of a radiographic imaging apparatus for the convenience of description. However, the radiographic imaging apparatus is not limited to the digital radiography apparatus but may be equally applied to any other radiographic imaging apparatus, such as a fluoroscopy apparatus, a cardiography apparatus, a mammography apparatus, or a computed tomography apparatus, which counts the number of photons to generate an image.

The radiographic imaging apparatus may include a radiation emission module 310 having a radiation emitting source 300 and a holder 410 having a table 411, on which an object 312 is placed.

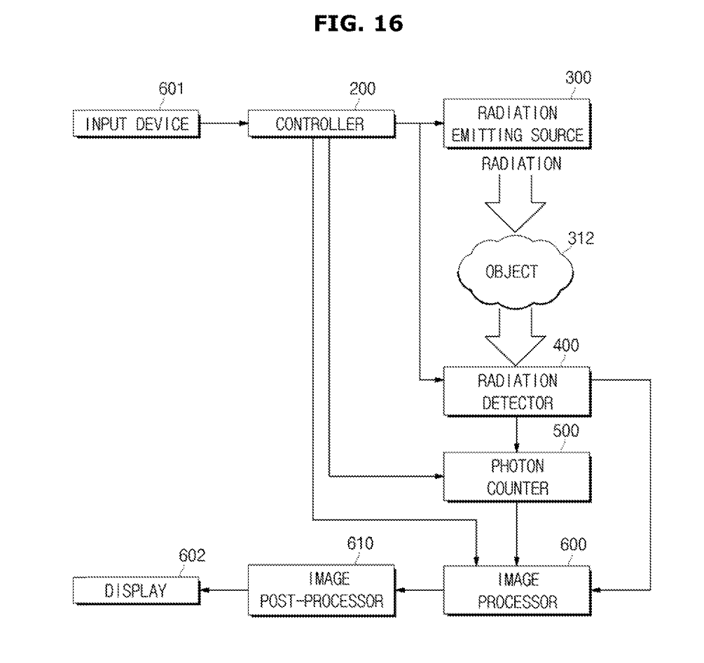

FIG. 16 is a view showing construction of an exemplary embodiment of the radiographic imaging apparatus.

As shown in FIG. 16, the radiographic imaging apparatus may include an input device 601, a controller 200, a radiation emitting source 300, a radiation detector 400, a photon counter 500, an image processor 600, and a display 602.

The input device 601 allows a user of the radiographic imaging apparatus to input predetermined information, instructions, or commands. Specifically, the input device 601 may allow various kinds of information, instructions, or commands, such as the number of times of radiation emission or the emission amount of radiation, regarding radiographic imaging or radiographic image processing to be input thereto and transmit the input information, instruction, or command to the controller 200.

In an exemplary embodiment, the input device 601 may include various user interfaces, such as various buttons, a keyboard, a mouse, a trackball, a track pad, a touchscreen panel, various levers, a handle, or a stick, directly installed in the radiographic imaging apparatus. The input device 601 may be directly installed in the radiographic imaging apparatus or may be provided in an additional workstation that may transmit and receive data to and from the radiographic imaging apparatus via a wired or wireless communication network.

The controller 200 may generate a predetermined control command and transmit the generated control command to the radiation emitting source 300, the radiation detector 400, the photon counter 500, or the image processor 600 to control overall operation of the radiographic imaging apparatus. Specifically, the controller 200 may receive a user instruction, a user command, or various kinds of information input through the input device 601 and control predetermined operation of the radiographic imaging apparatus using the received instruction, command, or information. Alternatively, the controller 200 may control predetermined operation of the radiographic imaging apparatus according to predefined setting.

For example, the controller 200 receives a radiographic imaging commencement signal to emit a predetermined amount of radiation to an object 312 input by a user through the input device 601 and controls the radiation emitting source 300 to emit radiation to the object 312 according to the received radiographic imaging commencement signal.

The radiation emitting source 300 emits radiation having predetermined energy to the object 312.

In a case in which the radiographic imaging apparatus is a digital radiography apparatus as shown in FIG. 15, the radiation emitting source 300 may be formed in the radiation emission module 310.

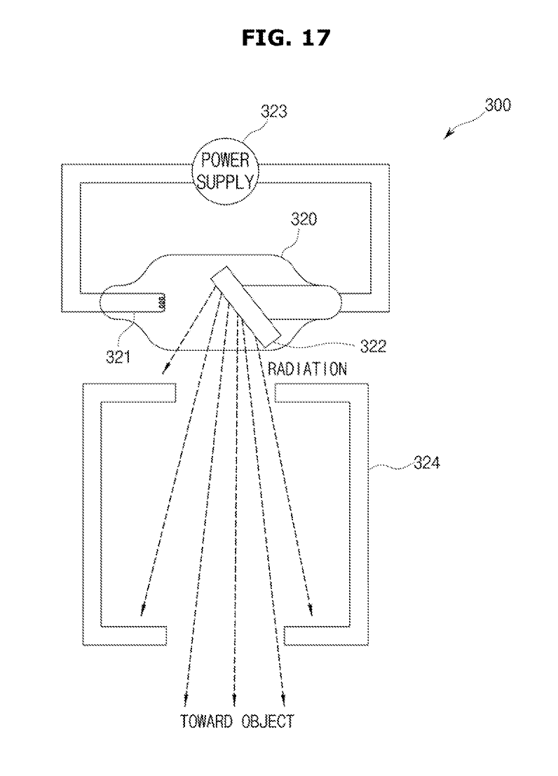

FIG. 17 is a view showing an exemplary embodiment of a radiation emitting source.

Referring to FIG. 17, a radiation emitting source 300 may include a radiation tube 320 and a power supply 323.

The power supply 323 may apply predetermined voltage to the radiation tube 320 according to the amount of radiation to be emitted or energy of radiation to be emitted.

As shown in FIG. 17, the radiation tube 320 may include a cathode filament 321 at which electrons are collected and an anode 322.

When predetermined voltage from the power supply 323 is applied to the radiation tube 320, electrons located at or around the cathode filament 321 in the radiation tube 320 move to the anode 322 while being accelerated according to the applied tube voltage. The electrons moving to the anode 322 while being accelerated collide with the anode 322 with the result that the electrons are suddenly decelerated. When the electrons are decelerated, radiation corresponding to the applied tube voltage is generated from the anode 322. As a result, the radiation emitting source 300 may generate radiation.

The radiation emitting source 300 may further include a collimator 324. As shown in FIG. 17, the collimator 324 may be installed on a radiation emission path. The collimator 324 may pass the radiation in a specific direction and may absorb or reflect the radiation transmitted in other directions to filter the radiation so that the radiation emitting source 300 emits the radiation in a predetermined range or in a predetermined direction. The collimator 324 may be made of a material, such as lead (Pb), which absorbs radiation. A user may control an emission direction or an emission range of radiation using the collimator 324.

The radiation emitting source 300 may change tube voltage applied from the power supply 323 to emit radiation having different energies to the object 312. The radiation emitting source 300 may apply the tube voltage several times to generate radiation corresponding to the applied number of the tube voltage.

The radiation detector 400 receives the radiation emitted from the radiation emitting source 300 and converts the received radiation into an electrical signal. The radiation detector 400 may be formed inside the table 411 of the holder 410 to receive radiation emitted from the radiation emitting source 300 and transmitted through the object 312. In a case in which the radiation emission module 310 having the radiation emitting source 300 emits radiation from above as shown in FIG. 15, the radiation detector 400 may be installed at the lower surface of the table 411 of the holder 410.

The radiation detector 400 may include a radiation detection panel 420 to receive radiation transmitted through the object 312 or directly reaching the radiation detector.

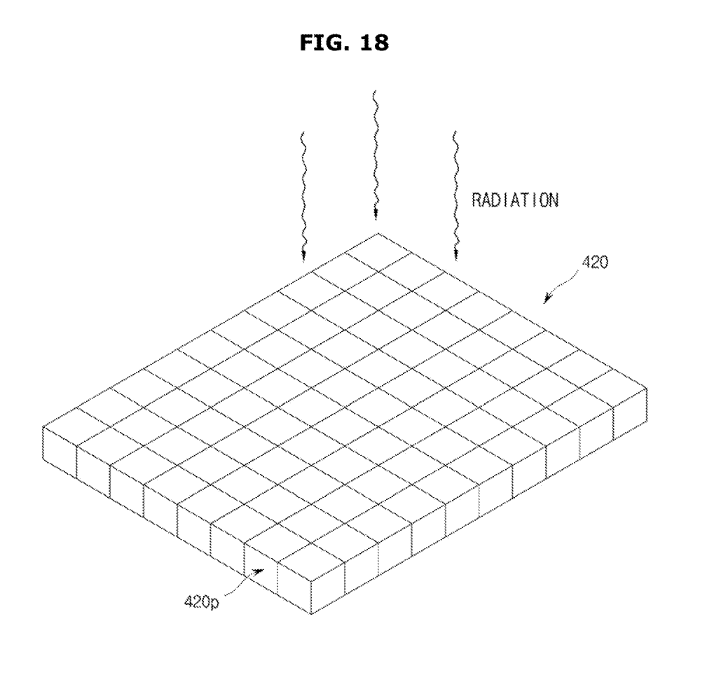

FIG. 18 is a view showing an exemplary embodiment of a radiation receiving panel.

As shown in FIG. 18, the radiation detection panel 420 may include at least one pixel 420p. In an exemplary embodiment, when radiation reaches the pixel 420p of the radiation detection panel 420, the pixel 420p may generate an electrical signal corresponding to the received radiation and convert the electrical signal into a radiation signal corresponding to the radiation. In an exemplary embodiment, when radiation reaches the pixel 420p of the radiation detection panel 420, the pixel 420p may output visible photons corresponding to the radiation, sense the visible photons, generate an electrical signal corresponding to the sensed visible photons, and convert the electrical signal into a radiation signal corresponding to the radiation.

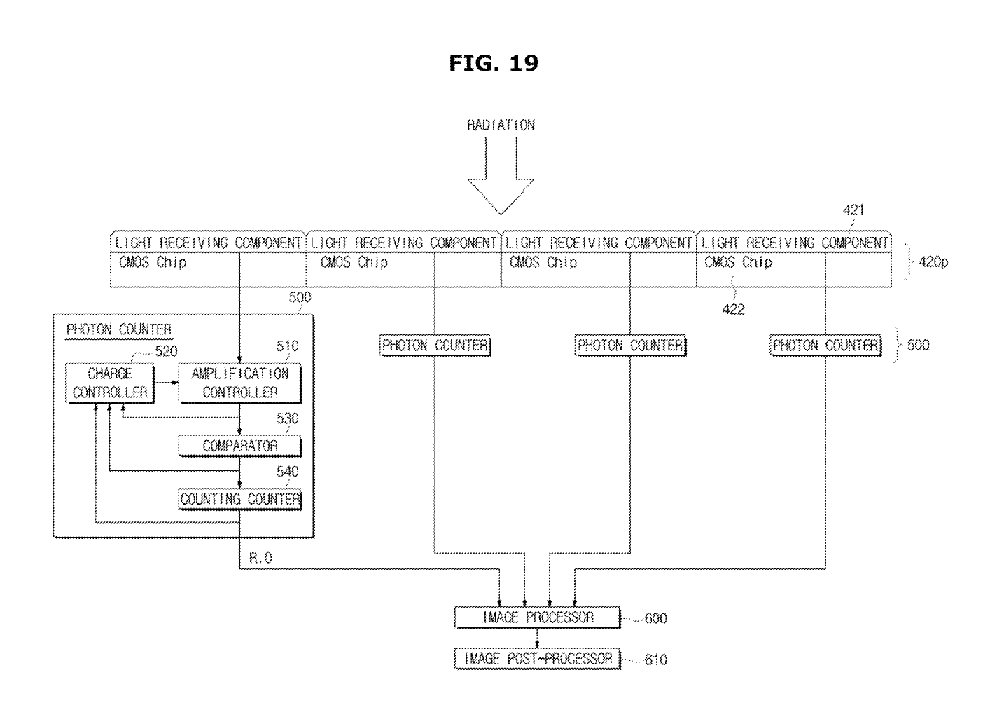

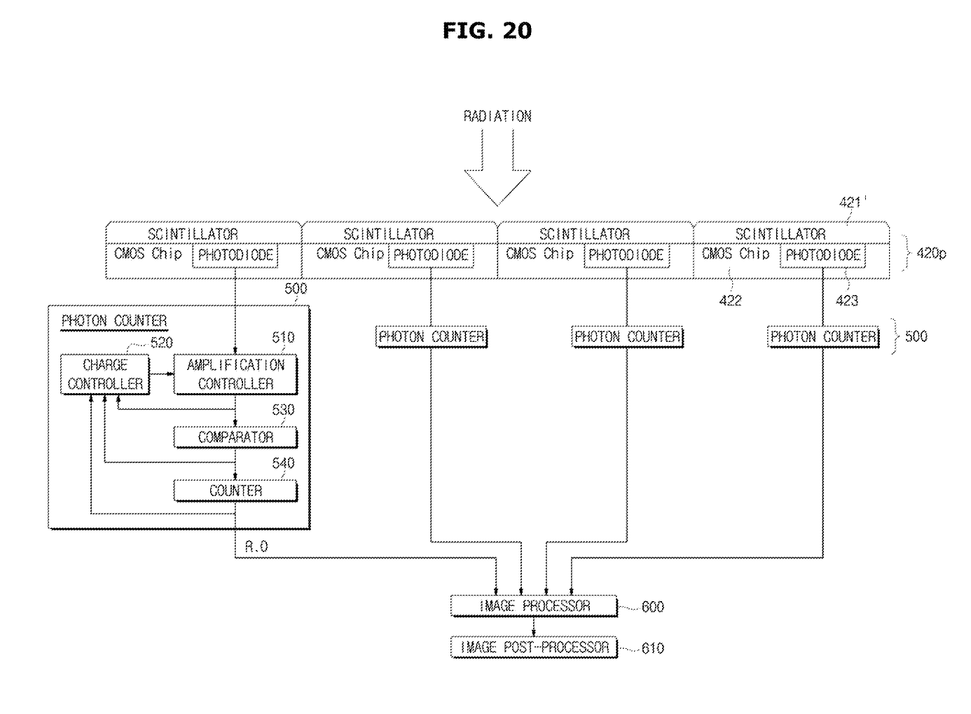

FIGS. 19 and 20 are views showing exemplary embodiments of a radiation receiving panel and a photon counter.

As shown in FIGS. 19 and 20, a radiation detector 400 may include a radiation detection panel 420 including a plurality of pixels 420p.

In an exemplary embodiment shown in FIG. 19, each pixel 420p of the radiation detection panel 420 may include a light receiving component 421 and a CMOS chip 422, at which the light receiving component 421 may be installed. In this case, the received radiation may be converted into a predetermined electrical signal, i.e., a radiation signal, in a direct mode.

The light receiving component 421 may be a photoconductor which may output a predetermined electrical signal, i.e., a radiation signal corresponding to the received radiation. The output radiation signal may be directly transmitted to a photon counter 500. The output radiation signal may be an electrical charge packet which may include negative charges.

In an exemplary embodiment shown in FIG. 20, each pixel 420p of the radiation detection panel 420 may include a light receiving component including a scintillator 421′, a light sensing component including a photodiode 423, and a CMOS chip 422, at which the light receiving component and the light sensing component may be installed. The received radiation may be converted into a predetermined electrical signal, i.e., a radiation signal, in an indirect mode.

The scintillator 421′ is a component to receive radiation and to output predetermined photons, such as visible photons, according to the received radiation.

The photodiode 423 may sense the visible photons output from the scintillator 421′ and output an electrical signal, i.e., a radiation signal. Similarly to the above description, the output radiation signal may be an electrical charge packet which may include negative charges.

In an exemplary embodiment, as shown in FIGS. 19 and 20, the pixels 420p of the radiation detection panel 420 may be electrically connected to a corresponding one of the photon counters 500.

Each photon counter 500 may count photons equal to or greater than reference energy to acquire predetermined data, such as intensity of radiation, needed to generate a radiographic image.

In an exemplary embodiment, as shown in FIGS. 19 and 20, each photon counter 500 may include an amplification controller 510, a charge controller 520, a comparator 530, and a counter 540.

The amplification controller 510 may charge a predetermined charger, such as a capacitor, with an input radiation signal to amplify the radiation signal and discharge an electrical signal charged in the predetermined charger, such as the capacitor.

In an exemplary embodiment, as shown in FIGS. 3, 4, and 6 to 10, the amplification controller 510 may include an amplifier and a charger which are connected to each other in parallel. A negative input terminal of the amplifier may be connected to an input terminal connected to a light receiving component or a photodiode, from which a radiation signal is output. A positive input terminal of the amplifier may be connected to reference voltage.

The charger of the amplification controller 510 may be charged with a radiation signal. In this case, as shown in FIGS. 2A and 2B, the charger is charged with the radiation signal for a predetermined charge time (t₀ to t₁) in the charger such that the amplification controller 510 may output an amplified radiation signal. When the amplified radiation signal is output, the charger is discharged for a predetermined discharge time (t₁ to t₂) such that the charger is charged with a new radiation signal.

The charge controller 520 may control charge or discharge of an electrical signal of the charger of the amplification controller 510.

Specifically, the charge controller 520 may control charge and discharge of a radiation signal of the amplification controller 510 using at least one of a variable resistor, a passive component, or an active component.

For example, as shown in FIGS. 3 and 4, the charge controller 520 may maximize a resistance value of at least one variable resistor during charge and minimize the resistance value of the variable resistor during discharge to control charge or discharge of a radiation signal of the charger of the amplification controller 510.

In addition, as shown in FIGS. 6 to 8, the charge controller 520 may use a passive component including a plurality of resistors and at least one switch. The charge controller 520 may select at least one of the resistors to change the resistance of the passive component to control charge or discharge of a radiation signal of the amplification controller 510. The charge controller 520 may control the resistance of the passive component to be the maximum during charge of the radiation signal and the resistance of the passive component to be the minimum during discharge of the radiation signal.

Moreover, as shown in FIGS. 9 and 10, the charge controller 520 may control charge or discharge of a radiation signal of the amplification controller 510 using an active component. The active component does not transmit additional current to the amplification controller 510 during charge of a radiation signal. In a case in which a radiation signal is to be discharged, the active component may transmit additional current to the amplification controller 510 to discharge the radiation signal. The active component may use voltage of the amplified radiation signal. The active component may transmit current corresponding to the voltage of the radiation signal to the 510 to discharge the radiation signal.

The charge controller 520 may control charge or discharge of a radiation signal of the amplification controller 510 based on a feedback signal.

Specifically, as shown in FIGS. 19 and 20, the charge controller 520 may receive an amplified radiation signal output from the amplification controller 510, a comparison result signal output from the comparator 530, or a result signal output from the counter 540 or receive an additional control signal generated based on the above signal and control charge or discharge of the radiation signal of the amplification controller 510 according to the received signal.

The comparator 530 may compare an electrical signal amplified by an amplification controller 510 with reference energy to determine whether the amplified electrical signal is greater or less than the reference energy and output a comparison result signal. The comparison result signal may be a binary signal. For example, in a case in which the amplified electrical signal is greater than the reference energy, the comparison result signal may be 1. On the other hand, in a case in which the amplified electrical signal is less than the reference energy, the comparison result signal may be 0.

The counter 540 may count photons equal to or greater than reference energy using the comparison result signal transmitted from the comparator 530 and output photon counted result information. The counted result information may be intensity of radiation.

The output counted result information may be read out by the image processor 600.

The image processor 600 may generate a radiographic image based on the counted result information output from the photon counter 500. For example, the image processor 600 may substitute predetermined image values into pixels of a radiographic image corresponding to the respective pixels of the radiation detection panel 420 according to intensity of radiation applied to the respective pixels of the radiation detection panel 420 to generate the radiographic image. More specifically, in a case in which the number of photons counted for a predetermined pixel of the radiation detection panel 420 is small or few, i.e., intensity of radiation is low, the image processor 600 may display a relatively dark color, such as black, on a pixel of the radiographic image corresponding to the predetermined pixel of the radiation detection panel 420 to generate a predetermined radiographic image. On the other hand, in a case in which the number of photons counted for a predetermined pixel of the radiation detection panel 420 is large, i.e., intensity of radiation is high, the image processor 600 may display a relatively bright color, such as white, on a pixel of the radiographic image corresponding to the predetermined pixel of the radiation detection panel 420 to generate a predetermined radiographic image.

The image processor 600 as described above may be a processor equipped in the radiographic imaging apparatus or a processor equipped in an additional workstation connected to the radiographic imaging apparatus via a wired or wireless communication network.

The radiographic image generated by the image processor 600 may be stored in a storage medium, such as an additional magnetic disc or a memory chip, and displayed on the display 602 provided in the radiographic imaging apparatus or the workstation.

The radiographic image output from the image processor 600 may be transmitted to an image post-processor 610. The image post-processor 610 may change brightness, color, contrast, or sharpness of the radiographic image to correct the radiographic image. According to exemplary embodiments, the image post-processor 610 may generate a three-dimensional stereoscopic radiographic image using a plurality of radiographic images. The post-processed radiographic image may be stored in a storage medium or transmitted to the display 602 provided in the radiographic imaging apparatus or the workstation such that the radiographic image may be displayed to a user.

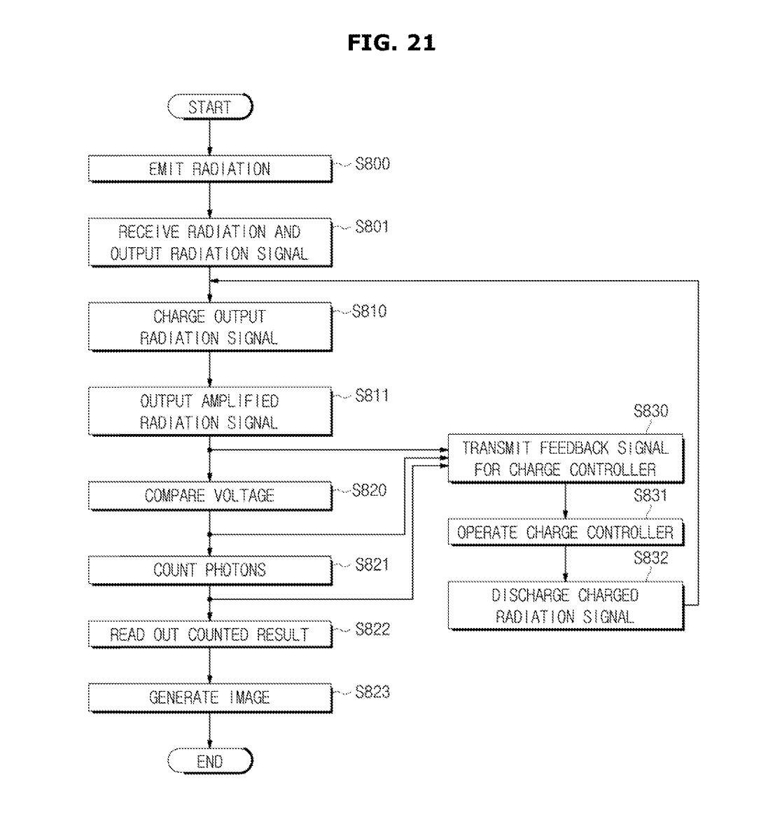

Hereinafter, a control method of the radiographic imaging apparatus will be described with reference to FIG. 21.

FIG. 21 is a flowchart showing an exemplary embodiment of a control method of the radiographic imaging apparatus.

Referring to FIG. 21, radiation is generated and emitted to an object 312 (operation S800). The emitted radiation is attenuated according to a predetermined attenuation rate while being transmitted through the object 312.

The radiation attenuated according to the predetermined attenuation rate while being transmitted through the object 312 and radiation directly transmitted through the surroundings of the object 312 are received and an electrical signal, i.e., a radiation signal, corresponding to the received radiation is output (operation S801).

The output radiation signal may be charged in the charger of the amplification controller (operation S810). In an exemplary embodiment, the charge controller may one of maximize the resistance value of the variable resistor, select and connect one of the resistors having the maximum resistance value, or interrupt predetermined current to charge the charger of the amplification controller. According to exemplary embodiments, electrical connection between the charger and the charge controller may be interrupted such that the radiation signal moves only to the charger of the amplification controller. The output radiation signal is charged in the charger of the amplification controller as voltage while being amplified.

The amplification controller may output and transmit the amplified radiation signal to the comparator (operation S811). The amplified radiation signal may be used as a feedback signal transmitted to the charge controller.

The comparator may compare the amplified radiation signal with reference voltage and output a comparison result signal based on the result of comparison (operation S820). The output comparison result signal may be transmitted to the counter. The comparison result signal may be transmitted to the charge controller such that the comparison result signal may be used as a feedback signal.

The counter may count the number of photons greater than the reference voltage according to the result of comparison (operation S821). The counter may output the photon counted result in the form of a counted result signal. The result signal may also be transmitted to the charge controller such that the result signal may be used as a feedback signal.

The image processor may read out the counted result (operation S822) and generate a predetermined radiographic image according to the read counted result (operation S823).

Meanwhile, the electrical signal charged in the charger at operation S810 may be discharged such that a new radiation signal may be charged. In this case, discharge of the radiation signal may be performed before, simultaneously with, or after at least one selected from among operations S820 to S822.

The feedback signal, such as the amplified radiation signal, the comparison result signal, or the photon counted result signal, may be transmitted to the charge controller to discharge the radiation signal (operation S830).

The charge controller may operate according to the feedback signal (operation S831). The charge controller may minimize the resistance value of the variable resistor, select and connect one of the resistors having the minimum resistance value, or introduce predetermined current to the amplification controller according to exemplary embodiments.

As the charge controller operates as described above, the radiation signal charged in the charger may be discharged (operation S832).

In a case in which a new radiation signal is output at operation S801, the charger, from which the radiation signal has been discharged, may be charged with the output radiation signal.

As is apparent from the above description, in the photon counting controller, the radiographic imaging apparatus, and the control method of the photon counting controller, input photons may be rapidly counted to acquire a radiographic image.

The electrical signal charged in the charger of the amplification controller may be rapidly discharged, thereby reducing a dead time needed for recharging to a desired level as needed.

Moreover, the radiographic imaging apparatus may rapidly count photons to acquire a plurality of radiographic images.

The described-above exemplary embodiments and advantages are merely exemplary and are not to be construed as limiting. The present teaching can be readily applied to other types of apparatuses. The description of exemplary embodiments is intended to be illustrative, and not to limit the scope of the claims, and many alternatives, modifications, and variations will be apparent to those skilled in the art.

What is claimed is:

1. A photon counting controller comprising:
an amplification controller configured to charge an input electrical signal, amplify the input electrical signal, and discharge the charged electrical signal;
a charge controller configured to control a charge and a discharge of the electrical signal of the amplification controller based on a received feedback signal; and
a measuring controller configured to compare a voltage of the amplified electrical signal with a reference voltage and count photons based on a result of comparison.

2. The photon counting controller according to claim 1, wherein the feedback signal comprises at least one of the amplified electrical signal and a control signal transmitted from the measuring controller.

3. The photon counting controller according to claim 1, wherein the amplification controller comprises a charger configured to charge the input electrical signal.

4. The photon counting controller according to claim 1, wherein the charge controller is connected to the amplification controller in parallel.

5. The photon counting controller according to claim 1, wherein the charge controller comprises a variable resistor whose value is varied according to the feedback signal.

6. The photon counting controller according to claim 1, wherein the charge controller comprises resistors configured to be connected to or disconnected from the amplification controller according to the feedback signal.

7. The photon counting controller according to claim 6, wherein the charge controller connects at least one of the resistors to the amplification controller in parallel to control the charge or the discharge of the electrical signal of the amplification controller.

8. The photon counting controller according to claim 1, wherein the charge controller applies current corresponding to the feedback signal to the amplification controller according to the feedback signal to control the discharge of the electrical signal of the amplification controller.

9. The photon counting controller according to claim 1, wherein the measuring controller generates a control signal for the charge controller according to the amplified electrical signal.

10. The photon counting controller according to claim 1, wherein the measuring controller comprises:
a comparator configured to compare the amplified electrical signal with a reference energy level to determine whether the amplified electrical signal is greater than, equal to, or less than the reference energy level; and
a counter configured to count the photons according to a determination result of the comparator.

11. The photon counting controller according to claim 10, wherein the comparator generates a control signal for the charge controller according to a result of a comparison.

12. A radiographic imaging apparatus comprising:
a radiation emitting source configured to emit radiation to an object;
a radiation detector configured to receive the radiation, convert the received radiation into an electrical signal, and output the converted electrical signal;
a photon counter configured to charge the electrical signal, consequently discharge the charged electrical signal, and measure intensity of the radiation transmitted through the object; and
a charge controller configured to control a charge and a discharge of the electrical signal of the photon counter, according to a feedback signal.

13. The radiographic imaging apparatus according to claim 12, wherein the charge controller comprises a variable resistor whose value is varied according to the feedback signal.

14. The radiographic imaging apparatus according to claim 12, wherein the charge controller comprises resistors configured to be connected to or disconnected from the photon counter according to the feedback signal, and connects at least one of the resistors to the photon counter to control the charge or the discharge of the electrical signal of the photon counter.

15. The radiographic imaging apparatus according to claim 12, wherein photon counter comprises:
an amplification controller configured to amplify an input electrical signal;
a comparator configured to compare the amplified electrical signal with a reference energy level to determine whether the amplified electrical signal is greater than, equal to, or less than the reference energy level; and
a counter configured to count the photons according to a determination result of the comparator, wherein
the amplification controller comprises a charger to charge the input electrical signal and to discharge the charged electrical signal.

16. A control method of a photon counting controller comprising:
charging a charger with an input electrical signal and amplifying the input electrical signal;
comparing a voltage of the amplified electrical signal with a reference voltage;
counting photons based on a result of a comparison; and
discharging the charged electrical signal according to a received feedback signal.

17. The control method according to claim 16, wherein the feedback signal comprises at least one of the amplified electrical signal and a control signal transmitted from an external device.

18. The control method according to claim 16, wherein the discharging comprises:
changing a resistance value of a variable resistor connected to the charger according to the feedback signal to discharge the charged electrical signal.

19. The control method according to claim 16, wherein the discharging comprises:
electrically connecting at least one resistor of a plurality of resistors connected to the charger, according to the feedback signal provided to the charger to discharge the charged electrical signal.

20. The control method according to claim 16, wherein the discharging comprises:
applying current corresponding to the feedback signal to the charger according to the feedback signal to discharge the charged electrical signal.
